(19) United States
(12) Patent Application Publication
(10) Pub. No.: US 2011/0164353 A1
(43) Pub. Date: Jul. 7, 2011

(54) ELECTRONIC DEVICE WITH FUNCTION EXPANSION CAPABILITIES

(75) Inventors: YANG-YUAN CHEN, Tu-Cheng (TW); MING-CHIH HSIEH, Tu-Cheng (TW)

(73) Assignee: HON HAI PRECISION INDUSTRY CO., LTD., Tu-Cheng (TW)

(21) Appl. No.: 12/688,847

(22) Filed: Jan. 15, 2010

(30) Foreign Application Priority Data
Jan. 7, 2010 (CN) 201010300098.4

(51) Int. Cl. H05K 5/00; H01R 13/44

(52) U.S. Cl. 361/679.01; 439/135

(57) ABSTRACT

An electronic device with function expansion capabilities includes a first connector, a second connector, and an expansion circuit. The first connector matches the second connector. The expansion circuit is connected between the first connector and the second connector. The expansion circuit of one electronic device communicates with the expansion circuit of another electronic device, in response to the first connector of one electronic device engaged with the second connector of another electronic device, so that the two expansion circuits are integrated together.

### BACKGROUND

1. Technical Field

The present disclosure relates to electronic devices and, particularly, to an electronic device with function expansion capabilities.

2. Description of Related Art

Some electronic devices, such as digital video recorders (DVRs), perform function expansion. For example, if two DVRs need to be integrated together, a transmission cable is connected between the DVRs to allow the expansion circuits of the two DVRs to interlink. However, because this expansion mode must use a transmission cable connected between the two DVRs, errors may be generated during data transfer between the DVRs.

### BRIEF DESCRIPTION OF THE DRAWINGS

FIG. 1 is a schematic, isometric view of an exemplary embodiment of an electronic device with function expansion capabilities.

FIG. 2 is an inverted view of the electronic device of FIG. 1.

FIG. 3 is a partial circuit diagram of the electronic device of FIG. 1.

FIG. 4 is an assembled, isometric view of two electronic devices of FIG. 1.

FIG. 5 is a schematic, isometric view of the electronic device of FIG. 1, together with a protecting cover.

### DETAILED DESCRIPTION

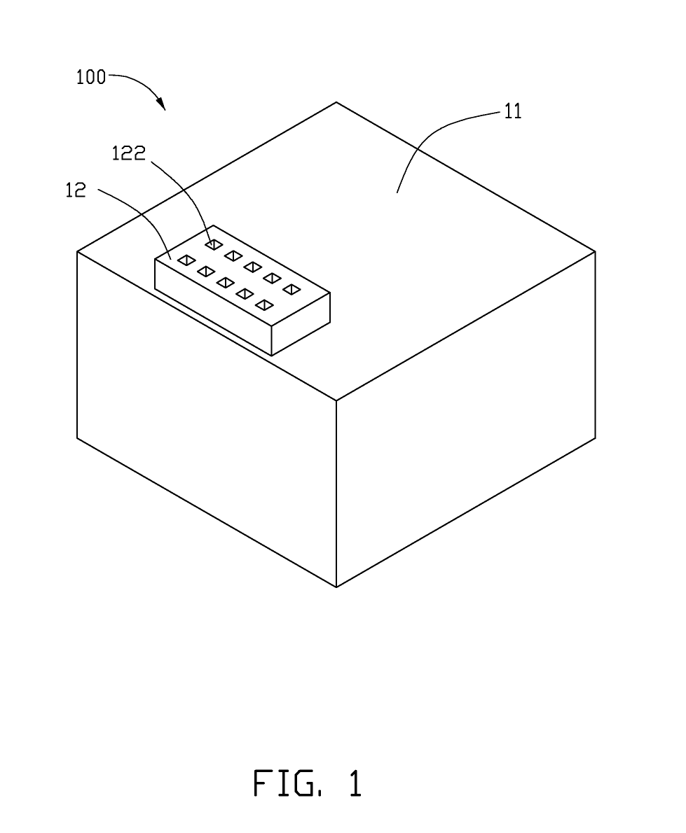

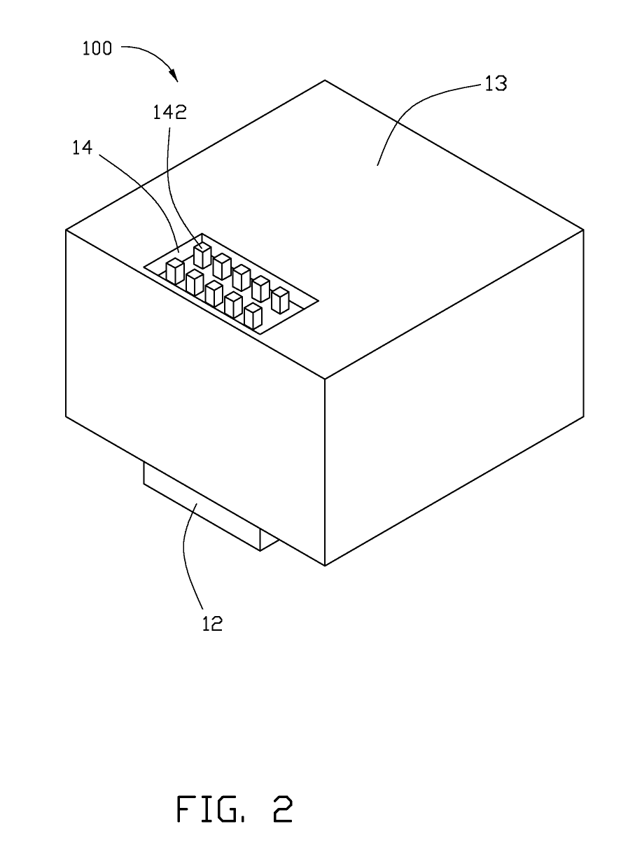

Referring to FIGS. 1 and 2, an exemplary embodiment of an electronic device 100 with function expansion capabilities includes a first connector 12 mounted on a first surface 11 of the electronic device 100, and a second connector 14 mounted on a second surface 13 of the electronic device 100 opposite to the first surface 11. The first connector 12 of the electronic device 100 can be inserted into the second connector 14 of another electronic device similar to the electronic device 100, namely the first connector 12 matches the second connector 14. The first connector 12 defines a plurality of jacks 122 therein. The second connector 14 includes a plurality of terminals 142 corresponding to the plurality of jacks 122.

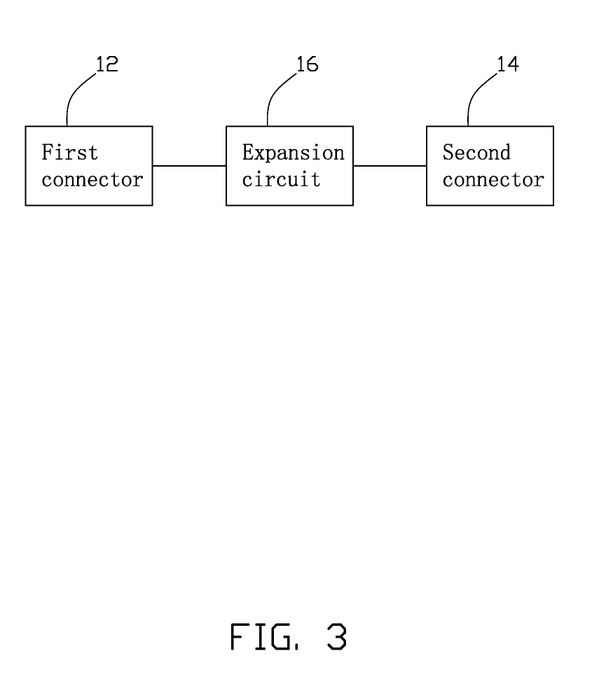

Referring to FIG. 3, in one embodiment, the electronic device 100 is a digital video recorder (DVR). The electronic device 100 includes an expansion circuit 16 connected between the first connector 12 and the second connector 14.

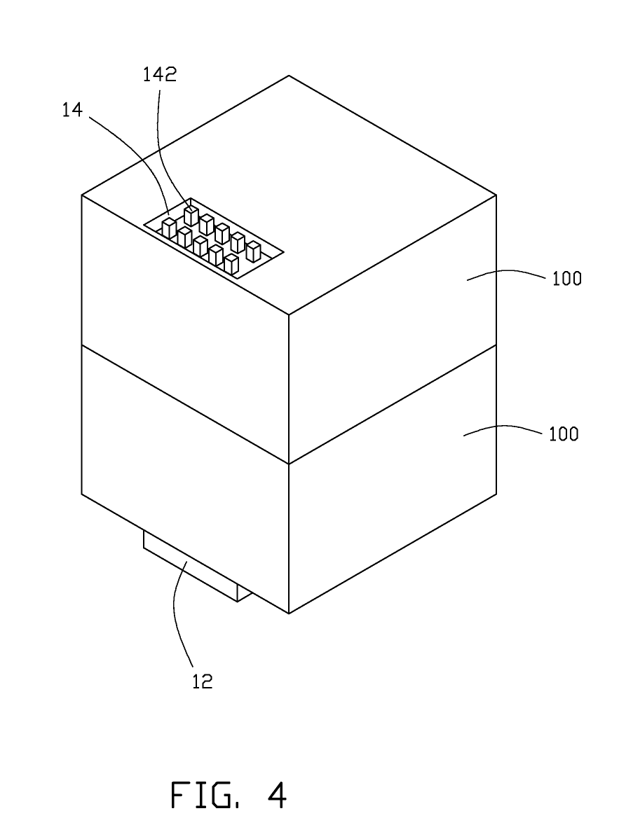

Referring to FIG. 4, if two electronic devices 100 need to be integrated together, the first connector 12 of one of the two electronic devices 100 is engaged with the second connector 14 of the other one of the two electronic devices 100. Therefore, the expansion circuit 16 of the one of the two electronic devices 100 communicates with the expansion circuit 16 of the other one of the two electronic devices 100, namely the two electronic devices 100 are integrated together. If more than two electronic devices 100 need to be integrated together, they can be connected together through engagement of the first connectors 12 and the second connectors 14. Because the electronic devices 100 are directly integrated by cableless connection via the first connectors 12 and the second connectors 14, data transmission error is unlikely.

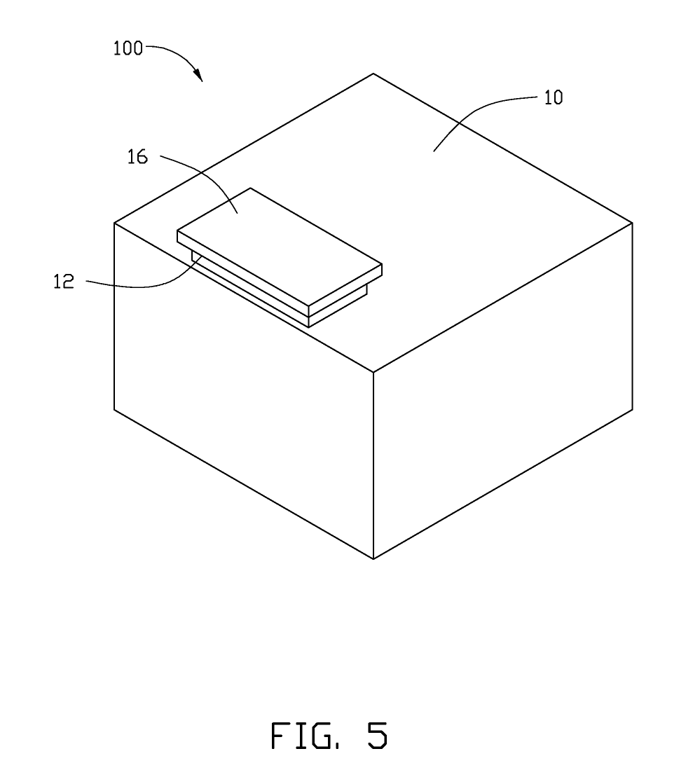

Referring to FIG. 5, to protect the first connector 12 and the second connector 14, the electronic device 100 may include two protecting covers 16 shielding the first connector 12 and the second connector 14. The two protecting covers 16 are also dust-proof.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. An electronic device with function expansion capabilities, the electronic device comprising:
a first connector;
a second connector, wherein the first connector matches the second connector;
and an expansion circuit connected between the first connector and the second connector;
wherein the expansion circuit of one electronic device is operable to communicate with the expansion circuit of another electronic device, in response to the first connector of the one electronic being engaged with the second connector of the another electronic device, or vice versa, so that the two expansion circuits are integrated together.

2. The electronic device of claim 1, further comprising a first surface and a second surface opposite to the first surface, wherein the first connector is mounted on the first surface, the second connector is mounted on the second surface.

3. The electronic device of claim 1, further comprising two protecting covers covered on the first connector and the second connector.

4. The electronic device of claim 1, wherein the electronic device is a digital video recorder.
